(19) United States
(12) Patent Application Publication
(10) Pub. No.: US 2005/0053127 A1
(43) Pub. Date: Mar. 10, 2005

(54) Equalizing device and method

(76) Inventors: Muh-Tian Shiue, Hsinchu City (TW); Ching-Kae Harris Tzou, Hsinchu (TW); Dong-Ming Chuang, Banciao City (TW); Chih-Feng Wu, Hsinchu City (TW)

Correspondence Address: SHAW PITTMAN;IP GROUP, 1650 TYSONS BOULEVARD, SUITE 1300, MCLEAN, VA, 22102, US

(21) Appl. No.: 10/883,821

(22) Filed: Jul. 6, 2004

Related U.S. Application Data
(60) Provisional application No. 60/485,386, filed on Jul. 9, 2003.
(60) Provisional application No. 60/484,313, filed on Sep. 23, 2003.

(51) Int. Cl. H03K 5/159

(52) U.S. Cl. 375/232

(57) ABSTRACT

An equalizing device includes a first filter, a target filter, an error determining device coupled with the first filter and the target filter, and a coefficient processor coupled with the error determining device. The first filter has a first set of coefficients and processes input signals transmitted through a communication channel to reduce channel response. The target filter has a second set of coefficients and generates a target channel output. The error determining device then processes an output of the first filter and the target channel output to generate error signals. The coefficient processor maintains constant at least one coefficient of the first or the second sets of coefficients and updates the remaining coefficients of the first and the second sets of coefficients based on the error signals.

### CLAIM OF PRIORITY

The present application claims priority from U.S. Provisional Application Ser. No. 60/485,386, entitled “Adaptive Algorithm for Time Domain Equalizer of DMT-based Receiver” and filed Jul. 9, 2003, and U.S. Provisional Application Ser. No. 60/484,313, entitled “Symbol Boundary Alignment for Discrete Multitone Transmission Systems” and filed Jul. 3, 2003, the contents of both provisional applications are incorporated herein by reference.

### BACKGROUND

1. Field of the Invention

The present invention relates to equalization. More particularly, the present invention relates to an equalizing device and method applicable to processing signals transmitted through a communication channel.

2. Background of the Invention

In the field of network communications, Asymmetric Digital Subscriber Line (“ADSL”) has become one of favorable options for providing network or Internet connections. ADSL is a type of DSL (Digital Subscriber Line) technology, which has been developed to increase the digital-data carrying capacity of traditional telephone lines. ADSL may share the same line as the telephone line by using higher frequencies than the voice band. To provide high-speed transmission of data over a telephone line, Discrete Multitone (“DMT”) modulation may be used.

As an example, DMT can be achieved by segmenting data into blocks, using an inverse fast Fourier transform (IFFT) operation at a transmitter, and using a fast Fourier transform (FFT) operation at a receiver. However, in a communication channel offering high rate transmission, intersymbol interference (“ISI”), which is the interference between separate symbols that are transmitted in sequence, may be generated due to a channel response. ISI, because of its effects on the signal quality, may impact the accuracy and the rate of signal transmission. One approach to reduce ISI is to employ an equalizing device or an equalizer at a receiver end to correct or compensate for the ISI caused by a communications channel.

However, traditional equalizing devices may require extensive computation to effectively correct or compensate for the ISI. As a result, they may be resource-consuming, which prevents them from offering fast response or high convergence rates under limited processing resources. Therefore, there is a need for an equalizing device and method capable of providing improved characteristics, reduced consumption of resources, or both.

### SUMMARY OF THE INVENTION

An equalizing device consistent with the present invention includes a first filter, a target filter, an error determining device coupled with the first filter and the target filter, and a coefficient processor coupled with the error determining device. The first filter has a first set of coefficients and processes input signals transmitted through a communication channel to reduce a channel response. The target filter has a second set of coefficients and generates a target channel output. The error determining device then processes output signals of the first filter and the target channel output to generate error signals. The coefficient processor maintains constant at least one coefficient of the first or the second sets of coefficients and updates the remaining coefficients of the first and the second sets of coefficients based on the error signals.

A coefficient updating device consistent with the present invention comprises an error determining device and a coefficient processor. The coefficient updating device may be used for an equalizing device, which has a first filter having a first set of coefficients for processing input signals and a target filter having a second set of coefficients for generating a target channel output. The error determining device processes output signals of the first filter and the target channel output to generate error signals. The coefficient processor maintains constant at least one coefficient of the first or the second sets of coefficients and updates the remaining coefficients of the first and the second sets of coefficients based on the error signals.

An equalizing method consistent with the present invention may include: receiving input signals transmitted through a communication channel; processing the input signals to reduce a channel response through using a first set of filtering coefficients and to generate equalized signals; generating a target channel output through using a second set of filtering coefficients; generating error signals from processing the equalized signals and the target channel output; and maintaining constant at least one coefficient of the first or the second sets of coefficients and updating the remaining coefficients of the first and the second sets of filtering coefficients based on the error signals.

A coefficient updating method consistent with the present invention may be applicable to an equalizing process. The equalizing process includes processing input signals using a first set of filtering coefficients to generate equalized signals and generating a target channel output using a second set of filtering coefficients. The coefficient updating method includes: generating error signals from processing the equalized signals and the target channel output; and maintaining constant at least one coefficient of the first or the second sets of coefficients and updating the remaining coefficients of the first and the second sets of filtering coefficients based on the error signals.

These and other elements of the present invention will be more fully understood upon reading the following detailed description in conjunction with the accompanying drawings.

### BRIEF DESCRIPTION OF DRAWINGS

FIG. 1 shows an exemplary relationship between a communication channel and an equalizer.

FIG. 2 illustrates an exemplary equalizer architecture using a least square algorithm.

FIG. 3 shows an embodiment of an equalizer architecture based on a minimum mean squared-error criteria.

FIG. 4 shows a system that updates the coefficients of an equalizer in the frequency domain.

FIG. 5 shows an exemplary block diagram of an equalizing device in embodiments consistent with the present invention.

FIG. 6 is a schematic flow chart diagram of an equalizing method in embodiments consistent with the present invention.

FIG. 7 show an impulse response from a simulation result in embodiments consistent with the present invention.

FIG. 8 shows a frequency response from a simulation result in embodiments consistent with the present invention.

FIG. 9 shows the convergence of channel signal-to-noise ratio from a simulation result in embodiments consistent with the present invention.

FIG. 10 demonstrates the signal power regulation behavior of digital automatic-gain-control gain from a simulation result in embodiments consistent with the present invention.

FIG. 11 shows signal-noise ratios at REVERB and MEDLEY states during initialization from a simulation result in embodiments consistent with the present invention.

FIG. 12 shows bit loading at REVERB and MEDLEY states from a simulation result in embodiments consistent with the present invention.

### DESCRIPTION OF EMBODIMENTS

Reference will now be made in detail to embodiments of the invention, examples of which are illustrated in the accompanying drawings.

Embodiments consistent with the present invention may include an equalizing device or an equalizing method employing and updating two sets of filtering coefficients to reduce errors associated with an equalized output. In one embodiment, one or more of the filtering coefficients may be maintained constant when the remaining coefficients are updated. In one embodiment, a device implementing the invention may cost-effectively determine the coefficients of an equalizing device. In addition, embodiments consistent with the invention may be used in a discrete multi-tone (“DMT”) transceiver, such as a DMT transceiver in an ADSL system, to reduce or eliminate the channel effects on signals transmitted through a communication channel, such as a telephone line. Without limiting the scope of the present invention, the following paragraphs will illustrate an equalizing device and an equalizing method using exemplary DMT-transceiver applications applicable to an ADSL system.

In an ADSL system, a DMT approach may be used to segment data into blocks or streams and use these streams to modulate one or more communication channels, such as a pair of conductive wires, twisted copper loops, or telephone lines. However, when the divided DMT symbols are transmitted through a communication channel, channel effect may cause or induce ISI (inter-symbol interference), which causes interference among neighboring symbols. To reduce or eliminate ISI, cyclic prefix (“CP”) of a certain length may be added in front of DMT symbols as a “guard time” between DMT symbols. Adding CPs separates the DMT symbols further apart in time and therefore may ease the impact from ISI.

For example, in a DMT transceiver, each DMT symbol with N samples to be transmitted is pre-pended by a CP with ν samples to reduce ISI impact at a receiving end. In one embodiment, if a channel response has a length equal to or less than ν+1 samples, the ISI introduced by channel dispersion can be eliminated completely from the received signal. However, adding CPs to existing DMT symbols increases the number of samples to be transmitted, thereby increasing the time for transferring the same number of DMT symbols. For example, the CP insertions may reduce the transmission efficiency from 1 to N/(N+ν). Accordingly, it is desirable to reduce the length of CPs to minimize the impact on transmission efficiency. For example, in the G.dmt standard of ADSL, the throughput efficiency is defined as N/(N+ν)=512/(512+32). Under that standard, a channel response having a length equal to 32 (samples) will have no ISI effect on the transmitted DMT symbols.

Unfortunately, channel response lengths of most communication channels, such as telephone lines or twisted copper loops, may be longer or much longer than 32 and may vary from channel to channel. To combat channel response dispersion, an equalizing device, such as an adaptive digital finite-impulse-response (“FIR”) filter or a time domain equalizer (“TEQ”), may be needed to shorten a channel response. For the purpose of evaluating a channel response, an “effective” communication channel in an ADSL system may include transmit filters and a hybrid circuit at a transmitting end, a twisted copper channel, a hybrid circuit and receiving filters at a receive end, and an adaptive digital FIR filter.

Optimal Shortening

In one embodiment, equalization is applicable for correcting or compensating for ISI caused by a communication channel, the response of which is unknown. To accommodate for the unknown response, an equalizer may be designed using a number of coefficients that may be adjusted to improve the effect of an equalizing process. The coefficients may be computed or updated for multiple times to obtain a “converged” result that better limit ISI impacts. For example, an adaptive equalization may be used and the coefficients may be continually adjusted based on the transmitted data or equalized data. And adaptive algorithms, such as least mean square (“LMS”) or recursive least square (RLS) algorithms, may be used.

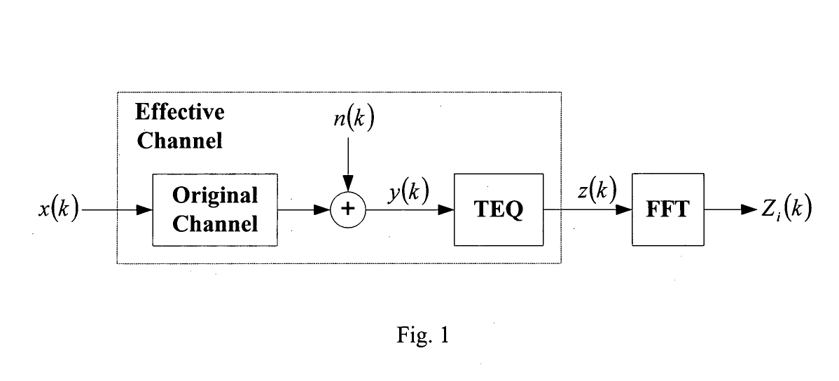

FIG. 1 shows an exemplary relationship between a communication channel and a time domain equalizer TEQ, which may be an adaptive digital FIR. In one embodiment, H denotes the transmission channel that may comprise transmit filters, a twisted copper loop, receive filters, and hybrid circuits. W denotes an adaptive digital FIR filter. An algorithm for shortening the channel response reflected in signal y(k) may use eigenvalues and eigenvectors to generate the TEQ coefficients, given the original channel response, the CP length, and the length of TEQ response. As an example, the effective channel response h_{eff} may be characterized as having two parts, h_{win} in the window of ν+1 consecutive samples and remaining part h_{wall}. One desirable shortening algorithm may generate the coefficients of W to minimize the energy h^{T}_{wall}h_{wall} while satisfying the constraint h^{T}_{win}h_{win}=A to avoid the trivial solution of w=[0, 0, . . . 0]^{T}. The shortening signal-to-noise ratio (“SSNR”) may be defined as follows:

$$SSNR = 10 log ( \frac{{h}_{win}^{T} {h}_{win}}{{h}_{wall}^{T} {h}_{wall}} ) = 10 log ( \frac{A}{{λ}_{min}} )$$

Least Square Shortening

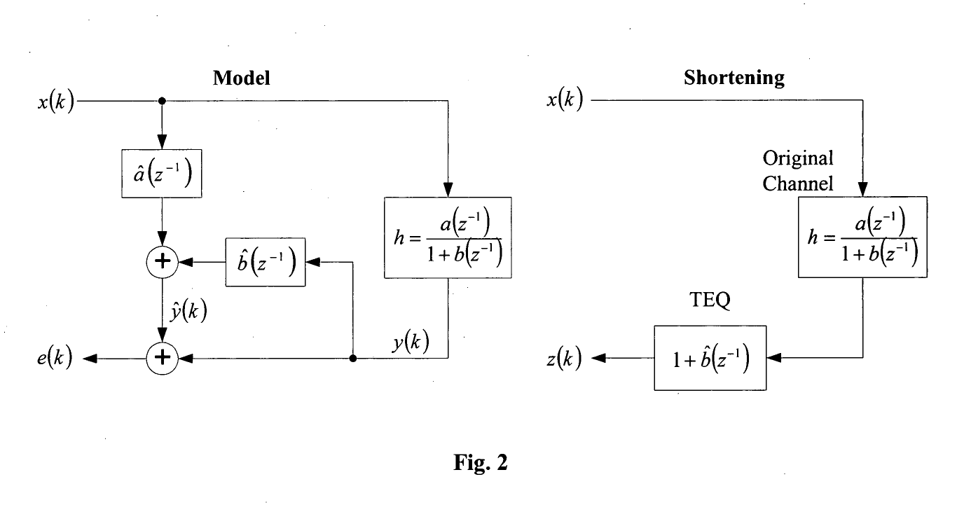

In another embodiment, a least square (“LS”) shortening approach may be used to shorten an effective channel response. A shortening algorithm, modeling the channel impulse response by a pole-zero model, may require the computation of eigenvalues and eigenvectors. In some embodiments, it may become difficult or complex to implement the algorithm in hardware or real-time DSP (digital signal processing) chips. Further, the original channel response may not be available in some instances. FIG. 2 illustrates an exemplary TEQ architecture using a least-square (“LS”) algorithm. A channel response may be represented as a pole-zero model with a transfer function of:

$$h ( {z}^{- 1} ) = \frac{a ( {z}^{- 1} )}{1 + b ( {z}^{- 1} )}$$

The LS algorithm may find a pole-zero model with the transfer function of:

$$\hat{h} ( {z}^{- 1} ) = \frac{\hat{a} ( {z}^{- 1} )}{1 + \hat{b} ( {z}^{- 1} )}$$

that best matches the original channel response. In other words, it may be desirable to minimize the square of the error as follows:
   e(n)=y(n)−ŷ(n).

In one embodiment, y(n) and ŷ(n) respectively denote the outputs of original channel and that of the best pole-zero model. A shortened effective channel response may approximate a transfer function of:

$${h}_{short} ( {z}^{- 1} ) = \frac{a ( {z}^{- 1} )}{1 + b ( {z}^{- 1} )} \cdot ( 1 + \hat{b} ( {z}^{- 1} ) ) \approx a ( {z}^{- 1} ) \approx \hat{a} ( {z}^{- 1} ) .$$

If the zeros of a chosen pole-zero model is less than ν+1, the shortened length of effective channel response can be less than that of CP to eliminate the ISI caused by a communication channel.

Two Channel Autoregressive Modeling

In another embodiment, two-channel autoregressive (“AR”) modeling may be used. The LS approach described above may require the calculation and the inversion of an autocorrelation matrix formed with the original channel input and output samples. In addition, the matrix is non-Toepliz. Therefore, it may be difficult to implement by hardware or real-time DSP chips in some instances. An AR modeling method may take the advantage of Levison algorithm, and the coefficients of a digital FIR filter may be solved numerically. In one embodiment, the AR modeling approach may reduce the best pole-zero model to an all-pole model to approximately cancel the poles of the original channel, because the pole-zero model of original channel in general has less than ν number of zeros. Accordingly, a shortened effective channel response can be approximately less than ν+1 to reduce ISI.

Minimum Mean Squared-Error in Time Domain

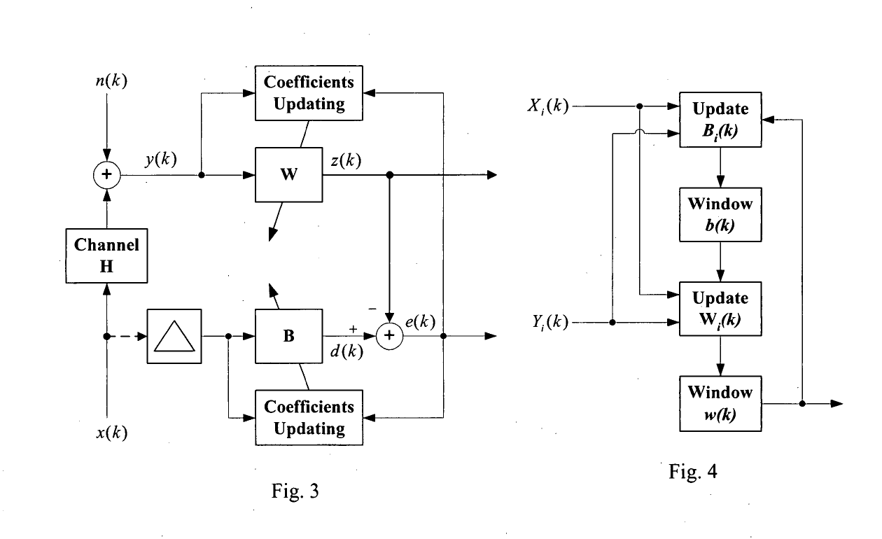

FIG. 3 shows an embodiment of a TEQ architecture based on a minimum mean squared-error (“MMSE”) criteria to shorten effective channel response. In one embodiment, H denotes the channel response of a communication channel, such as a twisted copper loop or a telephone line; W denotes an adaptive digital FIR filter to shorten the effective channel response; and B represents the target impulse response of the effective channel. The coefficients of W and B may be determined by an algorithm to minimize the mean squared-error between the outputs of W and B. According to the MMSE criteria, a cost function for establishing an error will be

$$\begin{matrix}E \{ {ⅇ}^{2} ( k ) \} = E \{ {( {W}^{T} Y - {B}^{T} {X}_{Δ} )}^{2} \} \\ = {W}^{T} {R}_{yy} W + {B}^{T} {R}_{xx . Δ} B - 2 {W}^{T} {R}_{yx . Δ} B\end{matrix}$$

where
   W=[w₀ w₁ . . . wₘ₋₁]^{T}
   B=[b₀ b₁ . . . b_{ν}]^{T}
   X_{Δ}=[x(k+Δ) x(k−1+Δ) . . . x(k−ν+Δ)]^{T}
   Y=[(k)y(k−1) . . . y(k−m+1)]^{T}

R_{yy} and R_{xx.Δ} respectively denote the autocorrelation martixes of the input signals of W and B. R_{yx.Δ} is the cross-correlation between x(k) and y(k). Note that R_{xx.Δ} and R_{yx.Δ} both depend on delay Δ.

For a given delay Δ, the optimal solution of W can be found by setting a partial diffentiation, according to the coefficient of W, of MMSE cost function to be zero. That is,

$$\frac{\partial ( E \{ {ⅇ}^{2} \} )}{\partial W} = 0 ⇒ {w}_{opt} = {R}_{yy}^{- 1} {R}_{yx , Δ} B$$

One then may substitute the optimal solution Wₒₚₜ into the MMSE cost function, and rewrite it to be
E{e²(k)}=B^{T}·(R_{xx.Δ}−R_{yx.Δ}^{T}(R_{yy}⁻¹)^{T}R_{yx.Δ})·B=B^{T}RB

Minimizing the above cost function, the optimal solution Bₒₚₜ can be found as the eigenvector corresponding to the smallest eigenvalue of the matrix R. Further, the unit-norm constraint Bₒₚₜ^{T}Bₒₚₜ=C or Wₒₚₜ^{T}Wₒₚₜ=C (1 is popular for C, so-called unit energy constraint) is applied to avoid the trivial solution of W=B=0. In practice, an iterative solution may be used to find a desirable solution in hardware or real-time DSP chips. In one embodiment, a LMS (least mean-square) algorithm can be applied to iteratively update W and B coefficients. If the updating step size is properly selected, the LMS algorithm can converge to the optimal solution within a reasonable time. Using a unit-energy constraint (“UEC”), the following equations provide examples of required operations and procedure to realize the LMS algorithm in time domain in one embodiment.

$$z ( k ) = {W}^{T} Y = {\sum }_{i = 0}^{m - 1} {w}_{i} ( k ) \cdot y ( k - i ) \\ d ( k ) = {B}^{T} {X}_{Δ} = {\sum }_{i = 0}^{v - 1} {b}_{i} ( k ) \cdot x ( k - i + Δ ) \\ e ( k ) = d ( k ) - z ( k ) \\ {w}_{i} ( k + 1 ) = {w}_{i} ( k ) + {μ}_{w} e ( k ) y ( k - i ) , i = 0 , 1 , 2 , … , m - 1. \\ {w}_{i} ( k + 1 ) = \frac{{w}_{i} ( k + 1 )}{{w}_{norm} ( k )} , i = 0 , 1 , 2 , … , m - 1 \\ ( if unit - norm constraint is applied to W ) {b}_{i} ( k + 1 ) = {b}_{i} ( k ) - {μ}_{b} e ( k ) x ( k - i + Δ ) , i = 0 , 1 , 2 , … , v . \\ {b}_{i} ( k + 1 ) = \frac{{b}_{i} ( k + 1 )}{{b}_{norm} ( k )} , i = 0 , 1 , 2 , … , v \\ ( if unit - norm constraint is applied to B ) {w}_{norm} ( k ) is defined as {w}_{norm} ( k ) ≡ \sqrt{{\sum }_{i = 0}^{m - 1} {w}_{i}^{2} ( k ) \\}$$

In one embodiment, normalization of w:

$${w}_{i} ( k + 1 ) = \frac{{w}_{i} ( k + 1 )}{{w}_{norm} ( k )}$$

is optional. It is applied when unit-norm (i.e., unit energy) constraint is applied. Minimum Mean Squared-Error in Frequency Domain

The embodiment noted above uses an LMS updating algorithm for updating the W and B coefficients in time domain. The W and B coefficients may also be updated in frequency domain. Time-domain and frequency-domain updating algorithms may be based on the same MMSE criteria to shorten effective channel response, although their coefficients are updated in different domains. FIG. 4 shows a system that updates the W and B coefficients of a TEQ in the frequency domain. As an example, the input signals of W and B are first transferred into the frequency domain by an FFT (fast Fourier transform) module. The coefficients of an equalizer W and those of a target response B are then updated in the frequency domain. In order to make sure that the length of shortened effective channel response is less than that of CP, the frequency responses of W and B are transferred to the time domain again by an IFFT (inverse FFT) module. Also, certain window operations may be applied to concentrate their associated energies within the predefined length. The procedure may be repeated until a desired performance merit is met.

Equalizing Device

In embodiments consistent with the present invention, an LMS algorithm may be used to minimize an MMSE cost function for an equalizing device. In one embodiment, to avoid the trivial solution of W=B=0, two constraints may be used: a unit energy constraint (UEC) and a unit tap constraint (UTC).

The following will describe an equalizing device, such as a TEQ, its algorithm, and one or more constraints that may eliminate a trivial solution.

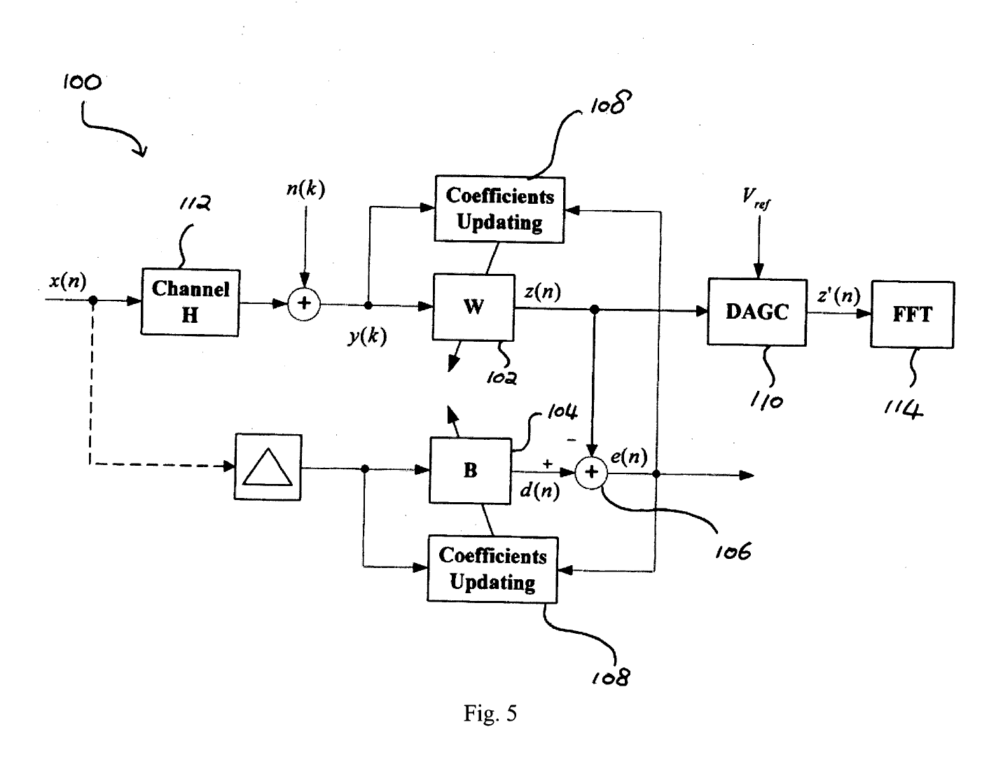

FIG. 5 shows an exemplary block diagram of an equalizing device, such as a TEQ, in embodiments consistent with the present invention. Referring to FIG. 5, equalizing device 100 may include first filter 102, target filter 104, error determining device 106, coefficient processor 108, and an optional device of gain control device 110. In one embodiment, equalizing device 100 may process input signals y(k) that have been transmitted through a communication channel 112 and may reduce channel response. Equalizing device 100 may be used in an ADSL communication channel. For example, communication channel 112 may be an ADSL communication channel comprising transmit filters and a hybrid circuit at a transmitting end, a twisted copper channel, and a hybrid circuit and receiving filters at a receive end. x(n) denotes signals generated at a transmitting end of the ADSL communication channel.

Still referring to FIG. 5, in one embodiment, first filter 102 may be an adaptive FIR (finite-impulse-response) filter and may process the input signals y(k) that have been transmitted through a communication channel 112 to reduce a channel response. Reducing the channel response may reduce the negative effects of ISI by reducing interference among neighboring symbols. First filter 102 may have a first set of coefficients, such as time-domain-equalizer filtering coefficients, that are used to reduce the channel response of the output z(n) generated by first filter 102. For example, output z(n) may be computed using the following formula:

$$z ( k ) = {W}^{T} Y = {\sum }_{i = 0}^{m - 1} {w}_{i} ( k ) \cdot y ( k - i )$$

, wherein wᵢ(k) is the first set of coefficients, which may be represented by a vector, and “·” denotes a multiplication. The coefficients wᵢ(k) may be adjusted or updated until reaching a converged result to improve the effect of reducing the channel response.

Target filter 104 may generate a target channel output d(n), which may be used as a basis for evaluating the output of first filter 102. In one embodiment, the target channel output may be obtained from an adaptive linear filter processing a sequence of samples of a locally generated training signal, which are generated at the receiving end of the communication channel. Target filter 104 has a second set of coefficients, such as time-domain-equalizer filtering coefficients, for generating the target channel output d(n). As an example, output d(n) may be computed using the following formula:

$$d ( k ) = {B}^{T} {X}_{Δ} = {\sum }_{i = 0}^{v - 1} {b}_{i} ( k ) \cdot x ( k - i + Δ )$$

, wherein bᵢ(k) is the second set of coefficients, which may be represented by a vector, and “·” denotes a multiplication. The coefficients bᵢ(k) may be adjusted or updated as described below to better reduce a channel response.

Except for the timing shift A shown in FIG. 5, the locally generated training signal should be the same as the one at input of channel H during an equalizer training state in one embodiment. In the ADSL standard, there are several states dedicated to equalizer training and, during these states, the receiver site has full knowledge of transmitted signal except for the channel delay and the start timing of the transmitted signal at channel input. These channel delay and starting timing of transmitted signal are represented as the timing shift Δ. Without loss of any generality, both the transmitted signal at channel input and locally generated training signal are denoted by x(n) and connected by dash line to represent their similarity. To synchronize the signals at wᵢ(k) and bᵢ(k) for proper equalizer training, the timing shift Δ needs to be estimated, and the injection timing of locally generated training signal x(n) into the target channel coefficients bᵢ(k) need to be adjusted accordingly before TEQ coefficients' training is activated. In one embodiment, to avoid ISI, the length ν of the target channel coefficients bᵢ(k) is equal to or smaller than the CP length. The coefficients bᵢ(k) may be adjusted or updated as illustrated above.

Referring to FIG. 5, error determining device 106 may couple with first filter 102 and target filter 104 for processing equalized output z(n) of first filter 102 and the target channel output d(n) from target filter 104 to generate error signals e(n). In one embodiment, error determining device 106 may be a subtracting device that subtracts z(n) from d(n), that is, e(k)=d(k)−z(k). In one embodiment, error signals e(n) may be computed using an MMSE (minimum mean squared-error) cost function.

Coefficient processor 108 is for updating the first set of coefficients of first filter 102 and/or the second set of coefficients of target filter 104. Referring to FIG. 5, coefficient processor 108 may include separate coefficient processors, one for first filter 102 and another for target filter 104, or use one single processor for updating one or more of those coefficients. In one embodiment, coefficient processor 108, during an updating process, maintains constant one or more coefficients of the first or the second sets of coefficients and updates only the remaining coefficients. During an updating process, Coefficient processor may update the remaining coefficients based on error signal e(n) generated by error determining device 106, using an updating algorithm, such as an LMS algorithm in time domain.

In one embodiment, coefficient processor 108 may update the remaining coefficients to reduce the difference between equalized output z(n) and target channel output d(n), such as to minimize results from an MMSE cost function. In one embodiment, coefficient processor 108, when updating the remaining coefficients, may maintain one or more coefficients of the first set coefficients at their initial values. In another embodiment, coefficient processor 108, when updating the remaining coefficients of the first and the second sets of coefficients, may maintain one or more coefficients of the second set coefficients at their initial values. For example, coefficient processor 108 may maintain the central tap of the second set of coefficients at a fixed value. The following illustrates exemplary formulas for updating or adapting the first and the second sets of coefficients in one embodiment.
wᵢ(k+1)=wᵢ(k)+μ_{w}e(k)y(k−i), i=0, 1, 2, . . . ,m−1
bᵢ(k+1)=bᵢ(k)−μ_{b} e(k)x(k−i+Δ), i=0, 1, 2, . . . , ν, and i≠ν/2
, wherein wᵢ(k+1) is the updated first set of coefficients, and bᵢ(k+1) is the updated second set of coefficients.

As shown by the formulas, the tap with a fixed value is the central tap of B. In some embodiments, an equalizing device or method consistent with the present invention may maintain one or more coefficients selected from the first or the second sets of coefficients at constant values. In one embodiment, an equalizing device may rely on firmware for identifying one or more coefficients to be maintained constant and one or more values at which the selected coefficients are to be maintained.

In another embodiment, the adaptations of w(k) and b(k) may employ the following formulas:
wᵢ(k+1)=wᵢ(k)+μ_{w}·sgn_{Q}(e(k))·y(k−i), i=0, 1, 2, . . . ,m−1.
bᵢ(k+1)=bᵢ(k)−μ_{b}·sgn_{Q}(e(k))·x(k−i+Δ), i=0, 1, 2, . . . , ν.
, wherein sgn_{Q} (x) quantizes x to its nearest pre-determined value, such as 2ⁿ, and n may be a positive or negative integer. In addition, if the step sizes μ_{w} and μ_{b} are properly chosen (i.e., 2 to the power of an integer value, respectively), the adaptation of wᵢ(k) and bᵢ(k) can be simplified to “shift and add” only. As a result, no multiplication and multiplier is needed and, thus, the hardware complexity for time-domain equalizer adjustment may be significantly reduced. Furthermore, instead of applying to the error signal e(k), the quantization function sgn_{Q}(x) can be applied to signals y(k) or x(k) as well for similar hardware complexity reduction.

In still another embodiment, the adaptations of w(k) and b(k) may employ alternative formulas, such as:
wᵢ(k+1)=wᵢ(k)+μ_{w}·e(k)·sgn_{Q}(y(k−i)), i=0, 1, 2, . . . , m−1.
bᵢ(k+1)=bᵢ(k)−μ_{b}·e(k)·sgn_{Q}(x(k−i+Δ)), i=0, 1, 2, . . . , ν.
or
wᵢ(k+1)=wᵢ(k)+μ_{w}·sgn_{Q}(e(k))·sgn_{Q}(y(k−i)), i=0, 1, 2, . . . , m−1.
bᵢ(k+1)=bᵢ(k)−μ_{b}·sgn_{Q}(e(k))·sgn_{Q}(x(k−i+Δ)), i=0, 1, 2, . . . , ν.

In some embodiments consistent with the present invention, the adaptations or updating of w(k) may use one of the several w(k) adaptation formulas noted above. Also, the adaptations or updating of b(k) may use one of the several b(k) adaptation formulas noted above.

Referring to FIG. 5, gain control device 110 may be coupled with first filter 102 to process equalized output z(n) and maintain the signal power of an equalizing device output. In one embodiment, gain control device 110 may wait until the converged result of z(n) is computed, which may occur after multiple updates of part of the first and the second sets of coefficients. In one embodiment, gain control device 110 may be a digital automatic gain control device (“DAGC”), which may include or use a first order feedback control system to adjust the level of output z′(n). As an example, output z′(n) may be computed using the following formula:
z′(k)=g_{DAGC}(k)·z(k)
, wherein g_{DAGC}(k) denotes the gain of DAGC 110, and “·” denotes a multiplication. In one embodiment, reference value V_{ref} may be provided as shown in FIG. 5, and the difference between the signal power of output z(n) and reference value V_{ref} may be fed back to tune gain g_{DAGC}. For example, Gain g_{DAGC} may be tuned adaptively to regulate the signal power at the output of equalizing device 100. Therefore, by setting an appropriate reference V_{ref}, DAGC may provide a mechanism for controlling the signal level for a following component, such as FFT module 114.

Referring to FIG. 5, in addition to the components illustrated above, FFT (fast Fourier transform) module 114 may be coupled with gain control device 110 to perform an FFT operation for a receiving end of an ADSL communication channel.

Accordingly, the equalizing device may employ an MMSE cost function, and an LMS updating algorithm to update some of the coefficients of the first and the second sets of coefficients in the time domain. In other words, the updating of the coefficients may avoid using an FFT module or an IFFT module for transforming coefficients to the frequency domain. Additionally, one or more fixed coefficients may eliminate a trivial solution during coefficient updates. For example, function B of target filter 104 will not converge to the trivial solution of zero. In some embodiments, equalizing device 100 may require much less computation power than conventional equalizers. For example, DAGC noted above may only need one multiplication plus two additions for each DMT symbol and one addition per sample. In contrast, a conventional LMS algorithm with UEC may have to calculate the norm of a set of coefficients and normalize all of the coefficients.

Equalizing Method

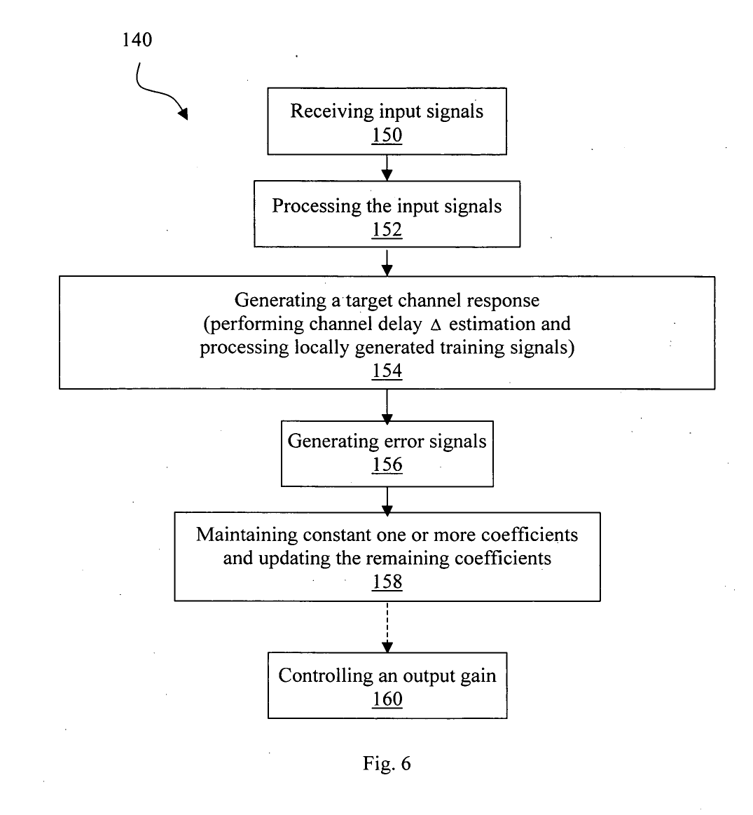

FIG. 6 is a schematic flow chart diagram of an equalizing method in embodiments consistent with the present invention. In one embodiment, an equalizing method 140 may include one or more of: receiving input signals at step 150; processing the input signals at step 152; generating a target channel output at step 154; generating error signals at step 156; and maintaining constant one or more coefficients and updating the remaining coefficients at step 158. Further, the equalizing method may also include an optional step of controlling an output gain at step 160. In some embodiments, several of the steps depicted in FIG. 6 and described below may optional.

At step 150, input signals transmitted through a communication channel are received. In one embodiment, the input signals comprise an ADSL transmission signals. The input signals may then be processed at step 152 to reduce channel response through using a first set of filtering coefficients and to generate equalized signals. In one embodiment, an adaptive digital FIR filter noted above may process the input signals based on the first set of filtering coefficients to generate the equalized signals.

At step 154, a target channel output may be generated by using a second set of filtering coefficients. In one embodiment, the target channel output may be generated by performing channel delay estimation and adjusting the injection timing of locally generated training signal. For example, the target channel output may be generated by a target filter noted above and processing a sequence of signal samples received from a local training signal generator with the use of estimated timing shift Δ (between channel input signal and training signal) to adjust injection timing of the training signal. In addition, both the first and the second sets of filtering coefficients may be time-domain-equalizer filtering coefficients. At step 156, error signals may be generated from processing the equalized signals generated at step 152 and the target channel output generated at step 154. As noted above, error signals may be generated from a subtracting operation and may be computed in the form of mean square error, such as by using an MMSE cost function.

At step 158, one or more coefficients of the first or the second sets of coefficients may be maintained constant, and the remaining coefficients of the first and the second sets of filtering coefficients may be updated based on the error signals. As noted above, the remaining coefficients may be updated to reduce the difference between the equalized signals and the target channel output, such as to minimize MMSE cost function results. In one embodiment, the remaining coefficients may be updated by an LMS algorithm in time domain

At step 158, one or more coefficients that are to be maintained may be selected from the first set of filtering coefficients, the second set of filtering coefficients, or both sets. As an example, the coefficient(s) may be maintained at its or their initial value(s). In one embodiment, coefficient processor 108 may maintain the central tap of the second set of coefficients at a fixed value, using the updating formulas illustrated above. In one embodiment, equalization firmware may be used for identifying one or more coefficients to be maintained constant and for identifying one or more values at which the coefficient(s) are to be maintained at.

In one embodiment, an equalizing method may also include an optional step of controlling an output gain at step 160. The output gain control may include using a first order negative feedback control system to process the equalized signals and control the output gain. In one embodiment, controlling the output gain may including using a formula of
z′(k)=g_{DAGC}(k)·z(k)
, wherein z′(k) is the output of the gain control device, g_{DAGC}(k) is a gain factor, and z(k) is the equalized signals. Examples of gain control and determination of g_{DAGC}(k) have been noted above.
   Simulation Results

Without limiting the scope of the present invention, the following paragraphs will illustrate experiments performed to identify the effect of an equalizing device or an equalization method in an ADSL system. In one experiment, numerical simulations were performed for test loops under ADSL standard T1.413, Issue 2. An exemplary test loop ANSI (American National Standards Institute) T1.601 Loop #3 may be used for the simulation. This loop represents a typical challenge to a downstream receiver because it has wire gauge combination and two bridge-taps near the ATU (ADSL Transceiver Unit) remote (ATU-R) side.

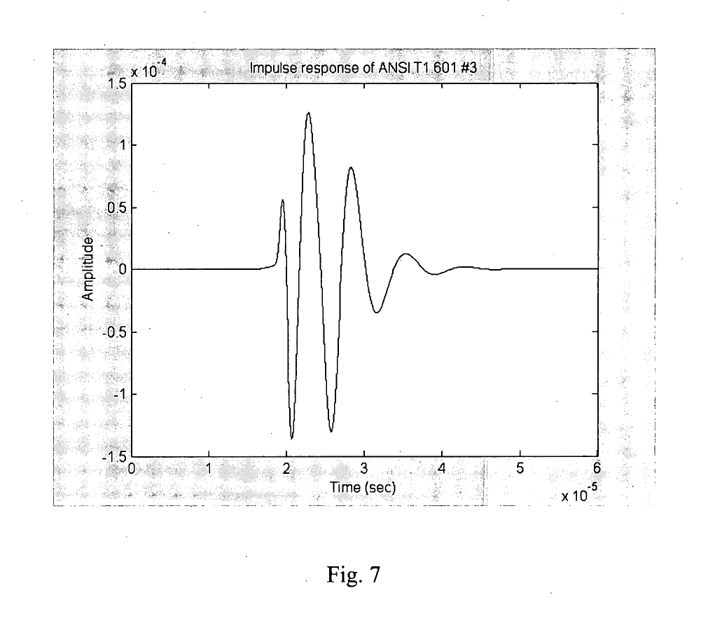

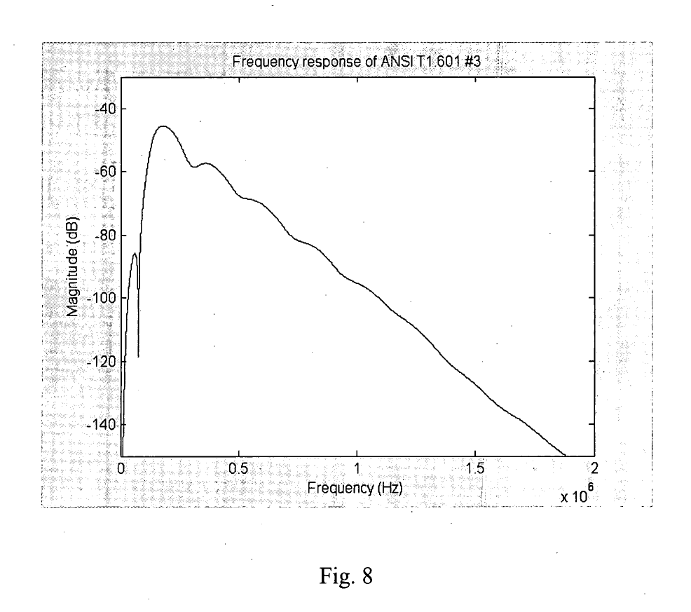

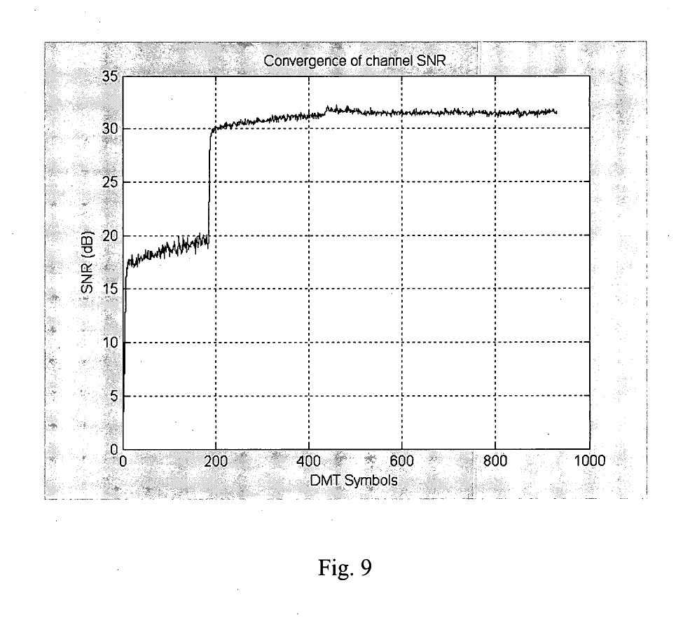

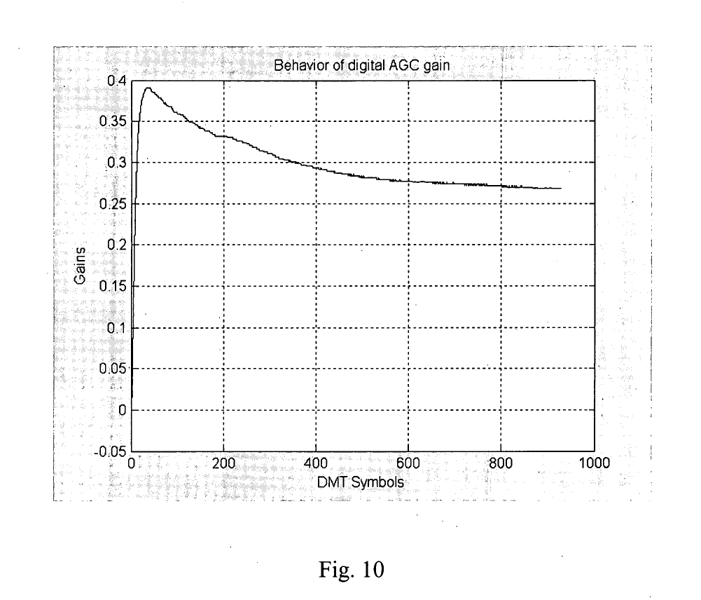

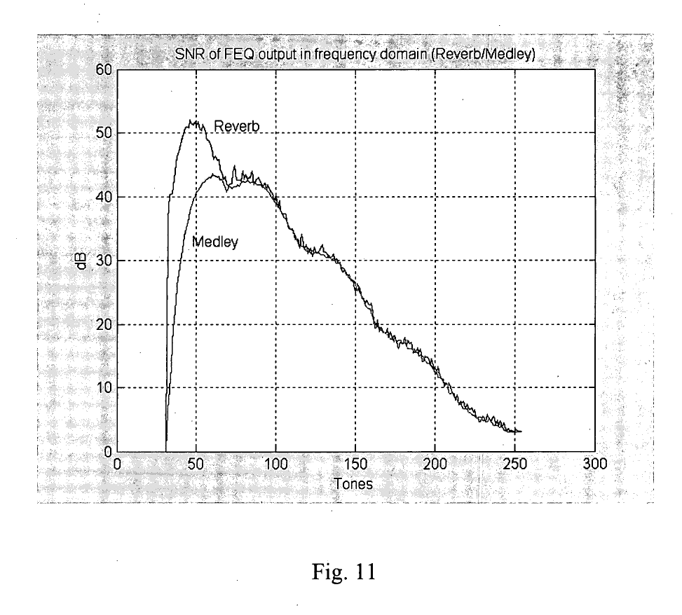

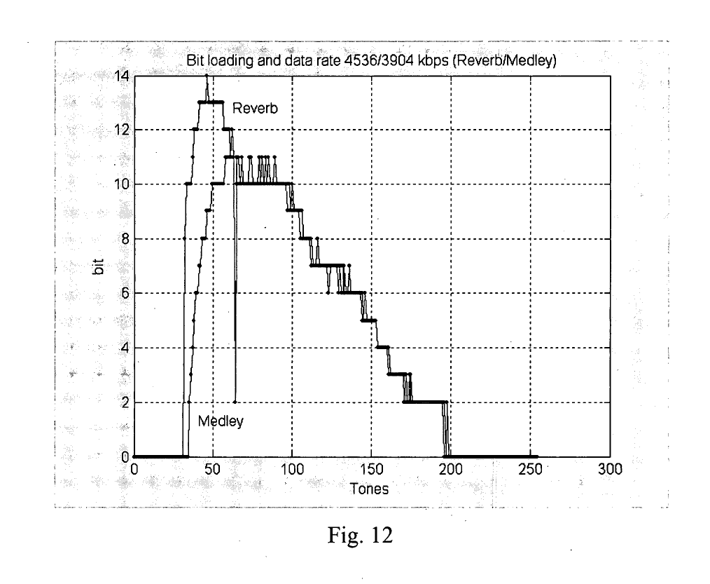

FIGS. 7 and 8 respectively show the impulse response and frequency responses of B and W functions. FIG. 9 shows the convergence of channel SNR when the additive background noise is −140 dBm. In one embodiment, in order to speed up the convergence, a multi-step size strategy may applied. FIG. 10 demonstrates the signal power regulation behavior of digital AGC gain. Further, numerical simulations are conducted in some experiments. FIGS. 11 and 12 respectively show the achieved SNRs at REVERB and MEDLEY states during initialization (T1.413 issue 2) and associated bit loading. In those simulations, it is assumed that the coding gain of forward error correction (FEC) is 4.5 dB. The achieved data is about 3.9 Mbps, which exceeds TR-048 (token ring 048) requirements.

The foregoing disclosure of the preferred embodiments of the present invention have been presented for purposes of illustration and description. They are not intended to be exhaustive or to limit the invention to the precise forms disclosed. Many variations and modifications of the embodiments described herein will be apparent to one of ordinary skill in the art in light of the above disclosure. The scope of the invention is to be defined by the claims appended hereto and their equivalents.

Further, in describing representative embodiments of the present invention, the specification may have presented methods or processes consistent with the present invention as a particular sequence of steps. However, to the extent that a method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to a method consistent with the present invention should not be limited to the performance of their steps in the order written, and one skilled in the art can readily appreciate that the sequences may be varied and still remain within the spirit and scope of the present invention.

1. An equalizing device comprising:
a first filter having a first set of coefficients, the first filter operable to process input signals transmitted through a communication channel to reduce a channel response;
a target filter having a second set of coefficients, the target filter operable to generate a target channel output;
an error determining device coupled with the first filter and the target filter, the error determining device operable to process an output of the first filter and the target channel output to generate error signals; and
a coefficient processor coupled with the error determining device, the coefficient processor operable to maintain constant at least one coefficient of the first or the second sets of coefficients and to update remaining coefficients of the first and the second sets of coefficients based on the error signals.

2. The device of claim 1, wherein the coefficient processor updates the remaining coefficients of the first set of coefficients with a formula of
wᵢ(k+1)=wᵢ(k)+μ_{w}e(k)y(k−i), i=0, 1, 2, . . . ,m−1
, wherein wᵢ(k) is the first set of coefficients, wᵢ(k+1) is an updated first set of coefficients, e(k) are the error signals, and y(k−i) are the input signals.

3. The device of claim 1, wherein the coefficient processor updates the remaining coefficients of the second set of coefficients with a formula of
bᵢ(k+1)=bᵢ(k)−μ_{b}e(k)x(k−i+Δ), i=0, 1, 2, . . . , ν, and i≠ν/2
, wherein bᵢ(k) is the second set of coefficients, bᵢ(k+1) is an updated second set of coefficients, and e(k) are the error signals.

4. The device of claim 1, wherein the coefficient processor updates the remaining coefficients of the first and second sets of coefficients with at least one of the following formulas:
wᵢ(k+1)=wᵢ(k)+μ_{w}·sgn_{Q}(e(k))·y(k−i), i=0, 1, 2, . . . , m−1.
bᵢ(k+1)=bᵢ(k)−μ_{b}·sgn_{Q}(e(k))·x(k−i+Δ), i=0, 1, 2, . . . ν.
wᵢ(k+1)=wᵢ(k)+μ_{w}·e(k)·sgn_{Q}(y(k−i)), i=0, 1, 2, . . . , m−1.
bᵢ(k+1)=bᵢ(k)−μ_{b}·sgn_{Q}(k)·sgn_{Q}(x(k−i+Δ)), i=0, 1, 2, . . . , ν.
wᵢ(k+1)=wᵢ(k)+μ_{w}·sgn_{Q}(e(k))·sgn_{Q}(y(k−i)), i=0, 1, 2, . . . , m−1.
bᵢ(k+1)=bᵢ(k)−μ_{b}·sgn_{Q}(e(k))·sgn_{Q}(x(k−i+Δ)), i=0, 1, 2, . . . , ν.
, wherein sgn_{Q} (x) quantizes x to a nearest pre-determined value 2ⁿ, and n is a positive or negative integer.

5. The device of claim 1, wherein the coefficient processor updates the remaining coefficients by a least mean square (LMS) algorithm in the time domain.

6. The device of claim 1, wherein the error determining device generates the error signals according to a minimum mean squared-error (MMSE) cost function.

7. The device of claim 1, wherein the first and the second sets of coefficients are time-domain-equalizer filtering coefficients.

8. The device of claim 1, further comprising equalization firmware for identifying the at least one coefficient to be maintained constant and identifying at least one initial value for the at least one coefficient.

9. The device of claim 1, wherein the first filter comprises an adaptive finite-impulse-response (FIR) filter.

10. The device of claim 1, further comprising a gain control device for processing the output of the first filter.

11. The device of claim 1, wherein the input signals comprise an Asymmetric Digital Subscriber Line (ADSL) transmission signals.

12. The device of claim 1, wherein the target filter processes samples of a training signal generated at a receiving end of the communication channel to generate the target channel output.

13. A coefficient updating device for an equalizing device, the equalizing device having a first filter having a first set of coefficients for processing input signals and a target filter having a second set of coefficients for generating a target channel output, the coefficient updating device comprising:
an error determining device for processing an output of the first filter and the target channel output to generate error signals; and
a coefficient processor, coupled with the error determining device, for maintaining constant at least one coefficient of the first or the second sets of coefficients and updating remaining coefficients of the first and the second sets of coefficients based on the error signals.

14. The device of claim 13, wherein the coefficient processor updates the remaining coefficients of the second set of coefficients with a formula of
bᵢ(k+1)=bᵢ(k)−μ_{b}e(k)x(k−i+Δ), i=0, 1, 2, . . . , ν, and i≠ν/2
, wherein bᵢ(k) is the second set of coefficients, bᵢ(k+1) is an updated second set of coefficients, and e(k) are the error signals.

15. The device of claim 13, wherein the coefficient processor updates the remaining coefficients of the first and second sets of coefficients with at least one of the following formulas:
wᵢ(k+1)=wᵢ(k)+μ_{w}·sgn_{Q}(e(k))·y(k−i), i=0, 1, 2, . . . , m−1.
bᵢ(k+1)=bᵢ(k)−μ_{b}·sgn_{Q}(e(k))x(k−i+Δ), i=0, 1, 2, . . . , ν.
wᵢ(k+1)=wᵢ(k)+μ_{w}·e(k)·sgn_{Q}(y(k−i)), i=0, 1, 2, . . . , m−1.
bᵢ(k+1)=bᵢ(k)−μ_{b}·e(k)·sgn_{Q}(x(k−i+Δ)), i=0, 1, 2, . . . , ν.
wᵢ(k+1)=wᵢ(k)+μ_{w}·sgn_{Q}(e(k))·sgn_{Q}(y(k−i)), i=0, 1, 2, . . . , m−1.
bᵢ(k+1)=bᵢ(k)−μ_{b}·sgn_{Q}(e(k))·sgn_{Q}(x(k−i+Δ)), i=0, 1, 2, . . . , ν.
wherein sgn_{Q}(x) quantizes x to a nearest pre-determined value 2ⁿ, and n is a positive or negative integer.

16. The device of claim 13, wherein the coefficient processor updates the remaining coefficients by a least mean square (LMS) algorithm in the time domain.

17. An equalizing method comprising:
receiving input signals transmitted through a communication channel;
processing the input signals to reduce a channel response through using a first set of filtering coefficients and to generate equalized signals;
generating a target channel output through using a second set of filtering coefficients;
generating error signals from processing the equalized signals and the target channel output; and
maintaining constant at least one coefficient of the first or the second sets of coefficients and updating remaining coefficients of the first and the second sets of filtering coefficients based on the error signals.

18. The method of claim 17, wherein updating the remaining coefficients of the first set of filtering coefficients comprises using a formula of
wᵢ(k+1)=wᵢ(k)+μ_{w}e(k)y(k−i), i=0, 1, 2, . . . ,m−1
, wherein wᵢ(k) is the first set of filtering coefficients, wᵢ(k+1) is an updated first set of filtering coefficients, e(k) is the error signals, and y(k−i) is the input signals.

19. The method of claim 17, wherein updating the remaining coefficients of the second set of filtering coefficients comprises using a formula of
bᵢ(k+1)=bᵢ(k)−μ_{b}e(k)x(k−i+Δ), i=0, 1, 2, . . . , ν, and i≠ν/2
, wherein bᵢ(k) is the second set of filtering coefficients, bᵢ(k+1) is an updated second set of filtering coefficients, and e(k) is the error signals.

20. The method of claim 17, wherein updating the remaining coefficients of the first and second sets of coefficients comprises using at least one of the following formulas:
wᵢ(k+1)=wᵢ(k)+μ_{w}·sgn_{Q}(e(k))·y(k−i), i=0, 1, 2, . . . , m−1.
bᵢ(k+1)=bᵢ(k)−μ_{b}·sgn_{Q}(e(k))x(k−i+Δ), i=0, 1, 2, . . . , ν.
wᵢ(k+1)=wᵢ(k)+μ_{w}·e(k)·sgn_{Q}(y(k−i)), i=0, 1, 2, . . . , m−1.
bᵢ(k+1)=bᵢ(k)−μ_{b}·e(k)·sgn_{Q}(x(k−i+Δ)), i=0, 1, 2, . . . , ν.
wᵢ(k+1)=wᵢ(k)+μ_{w}·sgn_{Q}(e(k))·sgn_{Q}(y(k−i)), i=0, 1, 2, . . . , m−1.
bᵢ(k+1)=bᵢ(k)−μ_{b}·sgn_{Q}(e(k))·sgn_{Q}(x(k−i+Δ)), i=0, 1, 2, . . . , ν.
, wherein sgn_{Q} (x) quantizes x to a nearest pre-determined value 2ⁿ, and n is a positive or negative integer.

21. The method of claim 17, wherein updating the remaining coefficients comprises updating the remaining coefficients by a least mean square (LMS) algorithm in the time domain.

22. The method of claim 17, wherein generating the error signals comprises generating the error signals according to a minimum mean squared-error (MMSE) cost function.

23. The method of claim 17, wherein the first and the second sets of filtering coefficients are time-domain-equalizer filtering coefficients.

24. The method of claim 17, further comprising using an equalization firmware for identifying the at least one coefficient to be maintained constant and identifying at least one initial value for the at least one coefficient.

25. The method of claim 17, further comprising controlling an output gain of the equalized signals.

26. The method of claim 17, wherein the input signals comprise an Asymmetric Digital Subscriber Line (ADSL) transmission signals.

27. The method of claim 17, wherein generating the target channel output comprises processing samples of a training signal generated at a receiving end of the communication channel.

28. A coefficient updating method for an equalizing process, the equalizing process comprising processing input signals using a first set of filtering coefficients to generate equalized signals and generating a target channel output using a second set of filtering coefficients, the coefficient updating method comprising:
generating error signals from processing the equalized signals and the target channel output; and
maintaining constant at least one coefficient of the first or the second sets of coefficients and updating remaining coefficients of the first and the second sets of filtering coefficients based on the error signals.

29. The method of claim 28, wherein updating the remaining coefficients of the second set of filtering coefficients comprises using a formula of
bᵢ(k+1)=bᵢ(k)−μ_{b}e(k)x(k−i+Δ), i=0, 1, 2, . . . , ν, and i≠ν/2
, wherein bᵢ(k) is the second set of filtering coefficients, bᵢ(k+1) is an updated second set of filtering coefficients, and e(k) is the error signals.

30. The method of claim 28, wherein updating the remaining coefficients of the first and second sets of coefficients comprises using at least one of the following formulas:
wᵢ(k+1)=wᵢ(k)+μ_{w}·sgn_{Q}(e(k))·y(k−i), i=0, 1, 2, . . . , m−1.
bᵢ(k+1)=bᵢ(k)−μ_{b}·sgn_{Q}(e(k))x(k−i+Δ), i=0, 1, 2, . . . , ν.
wᵢ(k+1)=wᵢ(k)+μ_{w}·e(k)·sgn_{Q}(y(k−i)), i=0, 1, 2, . . . , m−1.
bᵢ(k+1)=bᵢ(k)−μ_{b}·e(k)·sgn_{Q}(x(k−i+Δ)), i=0, 1, 2, . . . , ν.
wᵢ(k+1)=wᵢ(k)+μ_{w}·sgn_{Q}(e(k))·sgn_{Q}(y(k−i)), i=0, 1, 2, . . . , m−1.
bᵢ(k+1)=bᵢ(k)−μ_{b}·sgn_{Q}(e(k))·sgn_{Q}(x(k−i+Δ)), i=0, 1, 2, . . . , ν.
, wherein sgn_{Q}(x) quantizes x to a nearest pre-determined value 2ⁿ, and n is a positive or negative integer.

31. The method of claim 28, wherein updating the remaining coefficients comprises updating the remaining coefficients by a least mean square (LMS) algorithm in the time domain.
